(19) United States
(12) Patent Application Publication
(10) Pub. No.: US 2023/0341464 A1
(43) Pub. Date: Oct. 26, 2023

(54) SIGNAL ABNORMALITY DETECTION SYSTEM AND METHOD THEREOF

(71) Applicant: ASUSTeK COMPUTER INC., Taipei (TW)

(72) Inventors: Hung-Ju Lin, Taipei (TW); Yuan-I Tseng, Taipei (TW); Cheng-Wei Gu, Taipei (TW); Shu-Chiao Liao, Taipei (TW)

(21) Appl. No.: 17/979,860

(22) Filed: Nov. 3, 2022

(30) Foreign Application Priority Data
Apr. 25, 2022 (TW) 111115700

(51) Int. Cl. G01R 31/317; G01R 31/28; G06K 9/62

(52) U.S. Cl. CPC G01R 31/31708; G01R 31/2841; G06K 9/6256

(57) ABSTRACT

A signal abnormality detection system and a method thereof are provided. The signal abnormality detection system includes a signal sensor and a computing device. The signal sensor generates a sample signal to be tested through sensing. The computing device is signal-connected to the signal sensor to receive the sample signal to be tested, perform a correction on the sample signal to be tested, and perform a time-frequency transform on a one-dimensional signal generated after the correction to generate a two-dimensional time-frequency signal. The computing device reconstructs the two-dimensional time-frequency signal by using an abnormality detection model to calculate a reconstructed difference value. The computing device performs comparison to determine whether the reconstructed difference value is greater than a detection threshold to determine whether the sample signal to be tested is an abnormal sample.

### CROSS-REFERENCE TO RELATED APPLICATION

This application claims the priority benefit of Taiwan application serial No. 111115700, filed on Apr. 25, 2022. The entirety of the above-mentioned patent application is hereby incorporated by reference herein and made a part of the specification.

### BACKGROUND OF THE INVENTION

### Field of the Invention

The disclosure relates to a signal abnormality detection system for testing a cycle variable frequency signal and a method thereof.

### Description of the Related Art

In general, to detect whether a cycle variable frequency signal is normal, a one-dimensional signal is generally used to perform a test to determine whether the cycle variable frequency signal is an abnormal signal.

In an existing detection method, a one-dimensional pattern signal of a variable frequency signal to be tested is marked, and abnormality detection is performed by using the one-dimensional pattern signal. However, features of the variable frequency signal lie in a correspondence relationship between time and frequency, and the use of only the one-dimensional pattern signal causes a loss of some features. In addition, when a deviation between cycle variable frequency signals is not corrected, a model is prone to a misdetermination of a variable frequency signal to be tested with an excessively large cycle deviation, to affect a detection result and further affect the accuracy of abnormality detection.

### BRIEF SUMMARY OF THE INVENTION

According to the first aspect of this disclosure, a signal abnormality detection system is provided. The signal abnormality detection system includes a signal sensor and a computing device. The signal sensor generates a sample signal to be tested through sensing. The computing device is signal-connected to the signal sensor to receive the sample signal to be tested, perform a correction on the sample signal to be tested, and perform a time-frequency transform on a one-dimensional signal generated after the correction to generate a two-dimensional time-frequency signal. The computing device reconstructs the two-dimensional time-frequency signal by using an abnormality detection model to calculate a reconstructed difference value. The computing device performs comparison to determine whether the reconstructed difference value is greater than a detection threshold to determine whether the sample signal to be tested is an abnormal sample.

According to the second aspect of this disclosure, a signal abnormality detection method is provided. The signal abnormality detection method includes: collecting a sample signal to be tested; performing a correction on the sample signal to be tested to generate a corrected one-dimensional signal; performing a time-frequency transform on the one-dimensional signal to generate a two-dimensional time-frequency signal; reconstructing the two-dimensional time-frequency signal by using an abnormality detection model to calculate a reconstructed difference value; and performing comparison to determine whether the reconstructed difference value is greater than a detection threshold to determine whether the sample signal to be tested is an abnormal sample.

In summary, the signal abnormality detection system and method thereof of the disclosure effectively handle abnormality detection of a cycle variable frequency signal, and use an abnormality detection model to compute a two-dimensional time-frequency signal that has undergone correction and a frequency transform to retain more features during processing of a variable frequency signal, so that a calculated reconstructed difference value is used as a basis for determining whether there is an abnormal sample. Based on this, abnormality detection is performed, and the accuracy of abnormality detection is improved.

### BRIEF DESCRIPTION OF THE DRAWINGS

FIG. 1 is a schematic block diagram of a signal abnormality detection system according to an embodiment of the disclosure.

FIG. 2 is a schematic flowchart of performing sample correction according to an embodiment of the disclosure.

FIG. 3A is a schematic diagram of a standard sample signal used in the disclosure.

FIG. 3B is a schematic diagram of an uncorrected sample signal according to the disclosure.

FIG. 3C is a schematic diagram of a corrected sample signal according to the disclosure.

FIG. 4 is a schematic flowchart of training an abnormality detection model according to an embodiment of the disclosure.

FIG. 5A is a schematic signal diagram of a one-dimensional signal or a one-dimensional normal sample signal used in the disclosure.

FIG. 5B is a schematic signal diagram of a two-dimensional time-frequency signal, two-dimensional time-frequency test data, or two-dimensional time-frequency training data used in the disclosure.

FIG. 6 is a schematic flowchart of a signal abnormality detection method according to an embodiment of the disclosure.

FIG. 7A is a schematic diagram of an abnormal sample signal according to the disclosure.

FIG. 7B is a schematic diagram of a normal sample signal according to the disclosure.

### DETAILED DESCRIPTION OF THE EMBODIMENTS

Exemplary embodiments are provided below for detailed description. However, the embodiments are merely used as examples for description, and do not limit the protection scope of the disclosure. In addition, some components are omitted in the drawings in the embodiments, to clearly show technical features of the disclosure. The same reference numbers are used in the drawings to indicate the same or similar components.

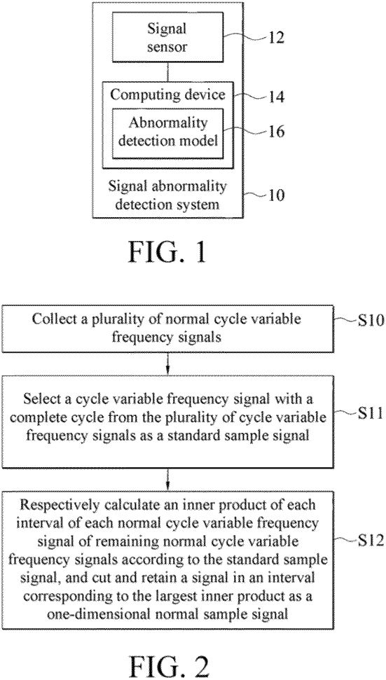

Referring to FIG. 1, a signal abnormality detection system 10 includes a signal sensor 12 and a computing device 14. The signal sensor 12 generates a sample signal to be tested through sensing. The sample signal to be tested is a cycle variable frequency signal. The computing device 14 is signal-connected to the signal sensor 12 in a wired or wireless manner, so that the sample signal to be tested sensed by the signal sensor 12 is transmitted to the computing device 14. After receiving the sample signal to be tested from the signal sensor 12, the computing device 14 performs a correction on the sample signal to be tested to generate a corrected one-dimensional signal, and then performs a time-frequency transform on the one-dimensional signal generated after the correction to generate a two-dimensional time-frequency signal, so that the corrected one-dimensional signal presents a change feature of each frequency and time to facilitate subsequent detection analysis. In an embodiment, the time-frequency transform is a short time Fourier transform (STFT). After obtaining the two-dimensional time-frequency signal, the computing device 14 reconstructs the two-dimensional time-frequency signal by using a built-in abnormality detection model 16 to calculate a reconstructed difference value. The reconstructed difference value is a difference value between the two-dimensional time-frequency signal being inputted into the abnormality detection model 16 and being outputted after being reconstructed by the abnormality detection model 16 (a difference value between an input and an output). The computing device 14 performs comparison to determine whether the reconstructed difference value is greater than a detection threshold to determine whether the sample signal to be tested is an abnormal sample. When the computing device 14 determines that the reconstructed difference value is greater than the detection threshold, it indicates that the sample signal to be tested is the abnormal sample. In comparison, when the computing device 14 determines that the reconstructed difference value is not greater than (including less than and equal to) the detection threshold, it indicates that the sample signal to be tested is a normal sample rather than an abnormal sample.

In an embodiment, that the computing device 14 performs a correction on the sample signal to be tested further includes: calculating an inner product of each interval of the sample signal to be tested according to a standard sample signal, and cutting and retaining a signal in an interval corresponding to the largest inner product as the one-dimensional signal. Therefore, the one-dimensional signal and the standard sample signal have the same cycle length, so as to unify size specifications of all signals for subsequent use.

In an embodiment, the signal sensor 12 is a microphone or an accelerometer or another electronic component that senses the cycle variable frequency signal. In an embodiment, to detect whether a sound signal played by a speaker is abnormal, the microphone used as the signal sensor 12 senses and receives the sound signal played by the speaker and generates the sample signal to be tested for subsequent detection.

In an embodiment, the computing device 14 is a computer host, a notebook, or another electronic device that operates independently, which is not limited in the disclosure.

In an embodiment, the abnormality detection model 16 in the computing device 14 is a denoising convolutional autoencoder model, which is a trained deep learning model. The abnormality detection model is obtained through training with a large number of cycle variable frequency signals based on a neural network to perform computation by using a feature that the denoising convolutional autoencoder model learns a relationship between an input signal and an output result.

To avoid a case that a deviation between cycle variable frequency signals causes a misdetermination of a model, in the disclosure, sample correction is performed on normal cycle variable frequency signals before the abnormality detection model 16 is trained, so that one-dimensional normal sample signals generated after the correction have consistent specification sizes, and the one-dimensional normal sample signals are used as training data of the abnormality detection model. The sample correction is first described in detail below.

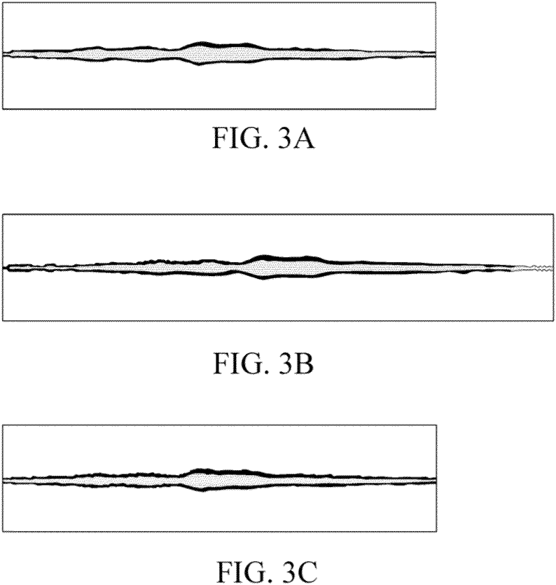

FIG. 2 is a schematic flowchart of performing a sample correction according to an embodiment of the disclosure. Referring to FIG. 1 and FIG. 2 together, as shown in step S10 first, a plurality of normal cycle variable frequency signals is collected. The plurality of normal cycle variable frequency signals is generated through sensing of the signal sensor 12, or is existing cycle variable frequency signals. As shown in step S11, a cycle variable frequency signal with a complete cycle is selected from the plurality of cycle variable frequency signals as a standard sample signal. As shown in step S12, an inner product of each interval of each normal cycle variable frequency signal of remaining normal cycle variable frequency signals is respectively calculated according to the standard sample signal, and a signal in an interval corresponding to the largest inner product is cut and retained as a one-dimensional normal sample signal. The corrected one-dimensional normal sample signal is used for subsequent training of the abnormality detection model 16. For actual schematic diagrams of sample signals, reference is made to FIG. 3A to FIG. 3C. FIG. 3A shows a standard sample signal. FIG. 3B shows an uncorrected sample signal of a normal cycle variable frequency signal before a correction. Based on the standard sample signal shown in FIG. 3A, after the uncorrected sample signal shown in FIG. 3B is processed by using the foregoing correction method, a corrected sample signal shown in FIG. 3C is obtained as a one-dimensional normal sample signal.

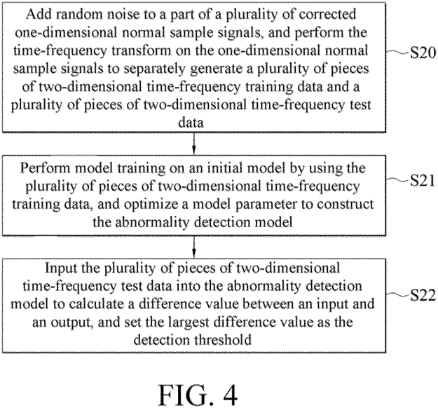

In an embodiment, a training process of the abnormality detection model 16 is shown in steps S20 to S22 of FIG. 4. Referring to FIG. 1 and FIG. 4 together, after obtaining the corrected one-dimensional normal sample signals, as shown in step S20, the computing device 14 divides the plurality of corrected one-dimensional normal sample signals into two parts, adds random noise to one part of the one-dimensional normal sample signals, and performs the time-frequency transform on the one-dimensional normal sample signals added with random noise, to generate a plurality of pieces of two-dimensional time-frequency training data. In addition, the computing device 14 directly performs the time-frequency transform on the other part of the one-dimensional normal sample signals to generate a plurality of pieces of two-dimensional time-frequency test data. The time-frequency transform is a short time Fourier transform. As shown in step S21, model training is repeatedly performed on an initial model of a denoising convolutional autoencoder model by using the plurality of pieces of two-dimensional time-frequency training data, and a model parameter is optimized to construct the abnormality detection model 16. As shown in step S22, the computing device 14 inputs the plurality of pieces of two-dimensional time-frequency test data into the abnormality detection model 16 for computing to calculate a difference value between each input and each output, and sets the largest difference value as a detection threshold, to use the detection threshold to determine whether the sample signal to be tested is an abnormal sample. The abnormality detection model 16 trained through steps S20 to S22 is formally installed in the computing device 14 for computational use in the disclosure.

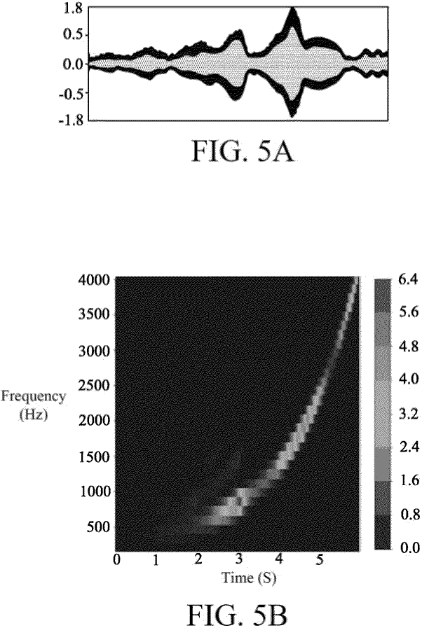

In an embodiment, an actual one-dimensional signal is shown in FIG. 5A. A frequency transform is performed on the one-dimensional signal shown in FIG. 5A to cause the actual one-dimensional signal to become a two-dimensional time-frequency signal shown in FIG. 5B, so that the two-dimensional time-frequency signal presents change features of each frequency and time to facilitate subsequent detection analysis. Definitely, two-dimensional time-frequency test data used in training is also shown in FIG. 5A. The two-dimensional time-frequency test data or two-dimensional time-frequency training data shown in FIG. 5B is obtained by performing a frequency transform on the two-dimensional time-frequency test data shown in FIG. 5A, so that the two-dimensional time-frequency test data or the two-dimensional time-frequency training data presents change features of each frequency and time to facilitate subsequent detection analysis.

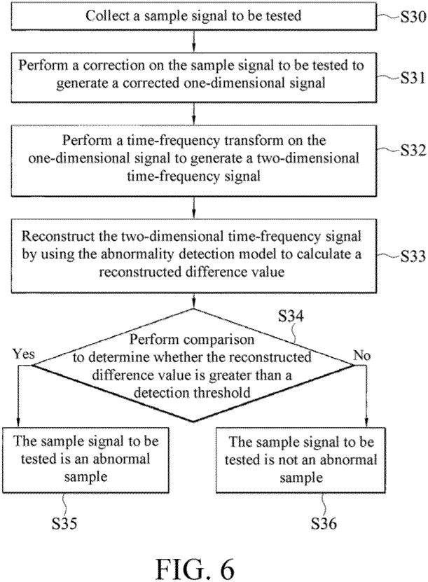

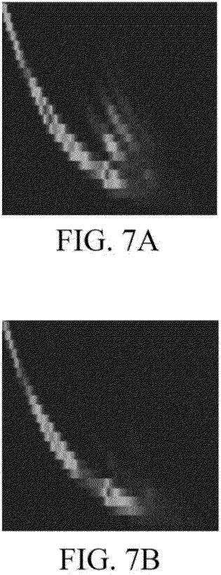

Referring to FIG. 1 and FIG. 6, a detailed process of the signal abnormality detection system 10 performing a signal abnormality detection method is shown in steps S30 to S36. In the signal abnormality detection method, first, as shown in step S30, a sample signal to be tested is collected. The sample signal to be tested is generated by the signal sensor 12 through sensing, or is an existing cycle variable frequency signal. As shown in step S31, the computing device 14 performs a correction on the sample signal to be tested to calculate an inner product of each interval of the sample signal to be tested according to a standard sample signal, and cuts and retains a signal in an interval corresponding to the largest inner product as a one-dimensional signal to generate a corrected one-dimensional signal. As shown in step S32, the computing device 14 performs a time-frequency transform on the one-dimensional signal (as shown in FIG. 5A) to generate a two-dimensional time-frequency signal (as shown in FIG. 5B). As shown in step S33, the computing device 14 reconstructs the two-dimensional time-frequency signal by using the abnormality detection model 16 installed therein to calculate a reconstructed difference value. As shown in step S34, the computing device 14 performs comparison to determine whether the reconstructed difference value is greater than a detection threshold to determine whether the sample signal to be tested is an abnormal sample. As shown in step S35, when the reconstructed difference value is indeed greater than the detection threshold, it indicates that the sample signal to be tested is an abnormal sample, as an abnormal sample signal shown in FIG. 7A. As shown in step S36, when the reconstructed difference value is not greater than (less than or equal to) the detection threshold, it indicates that the sample signal to be tested is not the abnormal sample. That is, the sample signal to be tested is a normal sample, for example, a normal sample signal shown in FIG. 7B.

In the disclosure, the normal sample signal is compared with the abnormal sample signal. If a difference from the abnormal sample signal is larger, a difference between a signal reconstructed by the abnormality detection model 16 and an inputted original signal is larger, as shown in FIG. 7A and FIG. 7B. The disclosure uses the feature to perform signal abnormality detection.

In summary, the signal abnormality detection system and method thereof of the disclosure effectively handle abnormality detection of a cycle variable frequency signal, and use an abnormality detection model to compute a two-dimensional time-frequency signal that has undergone correction and a frequency transform to retain more features during processing of a variable frequency signal, so that a calculated reconstructed difference value is used as a basis for determining whether there is an abnormal sample. Based on this, abnormality detection is performed, and the accuracy of abnormality detection is improved. In another aspect, in the disclosure, random noise is added to a process of training the abnormality detection model, and sample correction is performed on all the signals, so that the disclosure has a certain degree of tolerance in abnormality detection, which facilitates abnormality detection of a cycle variable frequency signal.

The embodiments described above are only used for explaining the technical ideas and characteristics of the disclosure to enable a person skilled in the art to understand and implement the content of the disclosure, and are not intended to limit the patent scope of the disclosure. That is, any equivalent change or modification made according to the spirit disclosed in the disclosure shall still fall within the patent scope of the disclosure.

What is claimed is:

1. A signal abnormality detection system, comprising:
a signal sensor, generating a sample signal to be tested through sensing; and
a computing device, signal-connected to the signal sensor to receive the sample signal to be tested, perform a correction on the sample signal to be tested, and perform a time-frequency transform on a one-dimensional signal generated after the correction to generate a two-dimensional time-frequency signal, the computing device reconstructs the two-dimensional time-frequency signal by using an abnormality detection model to calculate a reconstructed difference value, and the computing device performs comparison to determine whether the reconstructed difference value is greater than a detection threshold to determine whether the sample signal to be tested is an abnormal sample.

2. The signal abnormality detection system according to claim 1, wherein the correction comprises: calculating an inner product of each interval of the sample signal to be tested according to a standard sample signal, and cutting and retaining a signal in an interval corresponding to the largest inner product as the one-dimensional signal.

3. The signal abnormality detection system according to claim 1, wherein when the reconstructed difference value is greater than the detection threshold, it indicates that the sample signal to be tested is the abnormal sample; and when the reconstructed difference value is not greater than the detection threshold, it indicates that the sample signal to be tested is not the abnormal sample.

4. The signal abnormality detection system according to claim 1, wherein the sample signal to be tested is a cycle variable frequency signal.

5. The signal abnormality detection system according to claim 1, wherein a training method of the abnormality detection model comprises:
adding random noise to a part of a plurality of corrected one-dimensional normal sample signals, and performing the time-frequency transform on the one-dimensional normal sample signals to separately generate a plurality of pieces of two-dimensional time-frequency training data and a plurality of pieces of two-dimensional time-frequency test data;
performing model training on an initial model by using the plurality of pieces of two-dimensional time-frequency training data, and optimizing a model parameter to construct the abnormality detection model; and
inputting the plurality of pieces of two-dimensional time-frequency test data into the abnormality detection model to calculate a difference value between an input and an output, and setting the largest difference value as the detection threshold.

6. The signal abnormality detection system according to claim 5, wherein the initial model is a denoising convolutional autoencoder model.

7. The signal abnormality detection system according to claim 5, wherein a correction method of the corrected one-dimensional normal sample signals comprises:
collecting a plurality of normal cycle variable frequency signals;
selecting a cycle variable frequency signal with a complete cycle from the plurality of cycle variable frequency signals as a standard sample signal; and
respectively calculating an inner product of each interval of each of the remaining normal cycle variable frequency signals according to the standard sample signal, and cutting and retaining signals in intervals corresponding to the largest inner product as the one-dimensional normal sample signals.

8. The signal abnormality detection system according to claim 1, wherein the signal sensor is a microphone or an accelerometer.

9. The signal abnormality detection system according to claim 1, wherein the time-frequency transform is a short time Fourier transform.

10. A signal abnormality detection method, comprising:
collecting a sample signal to be tested;
performing a correction on the sample signal to be tested to generate a corrected one-dimensional signal;
performing a time-frequency transform on the one-dimensional signal to generate a two-dimensional time-frequency signal;
reconstructing the two-dimensional time-frequency signal by using an abnormality detection model to calculate a reconstructed difference value; and
performing comparison to determine whether the reconstructed difference value is greater than a detection threshold to determine whether the sample signal to be tested is an abnormal sample.

11. The signal abnormality detection method according to claim 10, wherein the correction comprises: calculating an inner product of each interval of the sample signal to be tested according to a standard sample signal, and cutting and retaining a signal in an interval corresponding to the largest inner product as the one-dimensional signal.

12. The signal abnormality detection method according to claim 10, wherein when the reconstructed difference value is greater than the detection threshold, it indicates that the sample signal to be tested is the abnormal sample; and when the reconstructed difference value is not greater than the detection threshold, it indicates that the sample signal to be tested is not the abnormal sample.

13. The signal abnormality detection method according to claim 10, wherein the sample signal to be tested is a cycle variable frequency signal.

14. The signal abnormality detection method according to claim 10, wherein a training method of the abnormality detection model comprises:
adding random noise to a part of a plurality of corrected one-dimensional normal sample signals, and performing the time-frequency transform on the one-dimensional normal sample signals to separately generate a plurality of pieces of two-dimensional time-frequency training data and a plurality of pieces of two-dimensional time-frequency test data;
performing model training on an initial model by using the plurality of pieces of two-dimensional time-frequency training data, and optimizing a model parameter to construct the abnormality detection model; and
inputting the plurality of pieces of two-dimensional time-frequency test data into the abnormality detection model to calculate a difference value between an input and an output, and setting the largest difference value as the detection threshold.

15. The signal abnormality detection method according to claim 14, wherein the initial model is a denoising convolutional autoencoder model.

16. The signal abnormality detection method according to claim 14, wherein a correction method of the corrected one-dimensional normal sample signals comprises:
collecting a plurality of normal cycle variable frequency signals;
selecting a cycle variable frequency signal with a complete cycle from the plurality of cycle variable frequency signals as a standard sample signal; and
respectively calculating an inner product of each interval of each of the remaining normal cycle variable frequency signals according to the standard sample signal, and cutting and retaining signals in intervals corresponding to the largest inner product as the one-dimensional normal sample signals.

17. The signal abnormality detection method according to claim 10, wherein the time-frequency transform is a short time Fourier transform.
